(19) United States
(12) Patent Application Publication
(10) Pub. No.: US 2014/0091344 A1
(43) Pub. Date: Apr. 3, 2014

(54) ILLUMINATION COMPONENT PACKAGE

(71) Applicant: LEXTAR ELECTRONICS CORPORATION, Hsinchu (TW)

(72) Inventors: Kuan-Chieh Wang, Miaoli City (TW); Cheng-Hung Yang, Taitung City (TW)

(73) Assignee: LEXTAR ELECTRONICS CORPORATION, Hsinchu (TW)

(21) Appl. No.: 13/775,824

(22) Filed: Feb. 25, 2013

(30) Foreign Application Priority Data
Oct. 3, 2012 (TW) 101136557

(51) Int. Cl. H01L 33/64

(52) U.S. Cl. CPC H01L 33/64
USPC 257/98

(57) ABSTRACT

An illumination component package includes a substrate, at least one illumination component, a dam and an encapsulating glue. The illumination component is mounted on the substrate. The dam surrounds the illumination component to form a accommodating space. The inner wall of the dam includes a plurality of glue adhering microstructures. The encapsulating glue is filled in the accommodating space.

### RELATED APPLICATIONS

This application claims priority to Taiwan Application Serial Number 101136557, filed Oct. 3, 2012, which is herein incorporated by reference.

### BACKGROUND

1. Technical Field

Embodiments of the present invention relate to an illumination apparatus. More particularly, embodiments of the present invention relate to an illumination component package.

2. Description of Related Art

In a typical LED package, the LED chip and the wires are all mounted on the dielectric layer. However, the LED chip is always hot because the LED chip generates heat when emitting light and the heat dissipation ability of the dielectric layer is poor. Therefore, the chip-on-board (COB) LED is developed for solving this issue.

In the COB LED package, the dielectric layer under the LED chip is removed, so that the LED chip is in direct contact with the heat dissipation substrate. As such, the thermal resistance therebetween can be lowered, and the temperature of the LED chip can be lowered as well when emitting light. In the COB LED package, a dam is introduced surrounding the LED chip, and a space is formed therebetween, in which the space is filled with a glue including phosphor.

However, the glue will peel from the dam due to the penetration of the moisture, such that the wires connected between the LED chips may be broken or disconnected, which not only affects the efficiency of the product, but also raises issues of safety.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In accordance with one embodiment of the present invention, an illumination component package includes a substrate, at least one illumination component, a dam and an encapsulating glue. The illumination component is mounted on the substrate. The dam surrounds the illumination component to form a accommodating space. An inner wall of the dam includes a plurality of glue adhering microstructures. The encapsulating glue is filled in the accommodating space.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of an illumination component package in accordance with the first embodiment of the present invention;

FIG. 2 is a partial top view of the illumination component package in FIG. 1;

FIG. 3 is a top view of an illumination component package in accordance with the second embodiment of the present invention;

FIG. 4 is a cross-sectional view of an illumination component package in accordance with the third embodiment of the present invention;

FIG. 5 is a cross-sectional view of an illumination component package in accordance with the fourth embodiment of the present invention;

FIG. 6 is a cross-sectional view of an illumination component package in accordance with the fifth embodiment of the present invention;

FIG. 7 is a cross-sectional view of an illumination component package in accordance with the sixth embodiment of the present invention;

FIG. 8 is a cross-sectional view of an illumination component package in accordance with the seventh embodiment of the present invention;

FIG. 9 is a cross-sectional view of an illumination component package in accordance with the eighth embodiment of the present invention;

FIG. 10 is a cross-sectional view of an illumination component package in accordance with the ninth embodiment of the present invention; and

FIG. 11 is a cross-sectional view of an illumination component package in accordance with the tenth embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### Embodiment 1

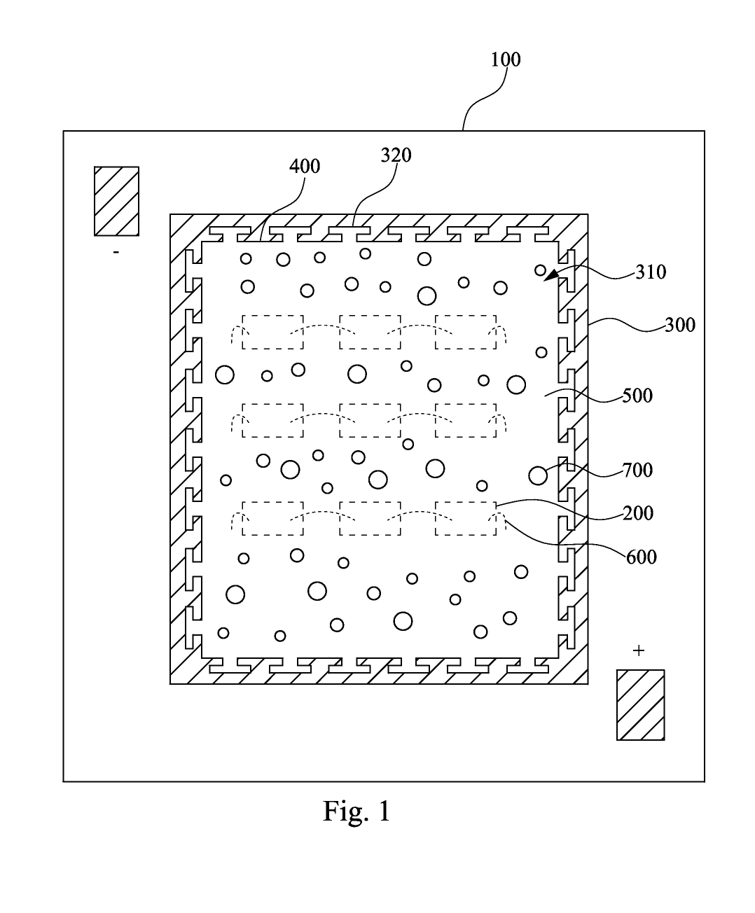

FIG. 1 is a top view of an illumination component package in accordance with the first embodiment of the present invention. As shown in FIG. 1, the illumination component package includes a substrate 100, at least one illumination component 200, a dam 300 and an encapsulating glue 500. The illumination component 200 is mounted on the substrate 100. The dam 300 surrounds the illumination component 200 to form a accommodating space 310. An inner wall 320 of the dam 300 includes a plurality of glue adhering microstructures 400. The encapsulating glue 500 is filled in the accommodating space 310.

In this embodiment, the glue adhering microstructures 400 are protruded on the inner wall 320 of the dam 300, and the encapsulating glue 500 is adhered to the glue adhering microstructures 400 and the inner wall 320, so that the contacting area between the dam 300 and the encapsulating glue 500 can be increased, thereby increasing the adhering strength between the encapsulating glue 500 and the dam 300, so as to prevent the moisture from penetrating therebetween and to prevent the encapsulating glue 500 peeling from the dam 300.

In this embodiment, the dam 300 surrounds the illumination component 200 along a direction, and the glue adhering microstructures 400 are arranged along that direction of the dam 300 surrounding the illumination component 200. Specifically, the dam 300 may be a rectangular ring structure. In other words, the inner wall 320 of the dam 300 is rectangular. The glue adhering microstructures 400 are arranged along the rectangular inner wall 320. As shown in FIG. 1, in the top view, all of the glue adhering microstructures 400 form a substantially rectangular profile.

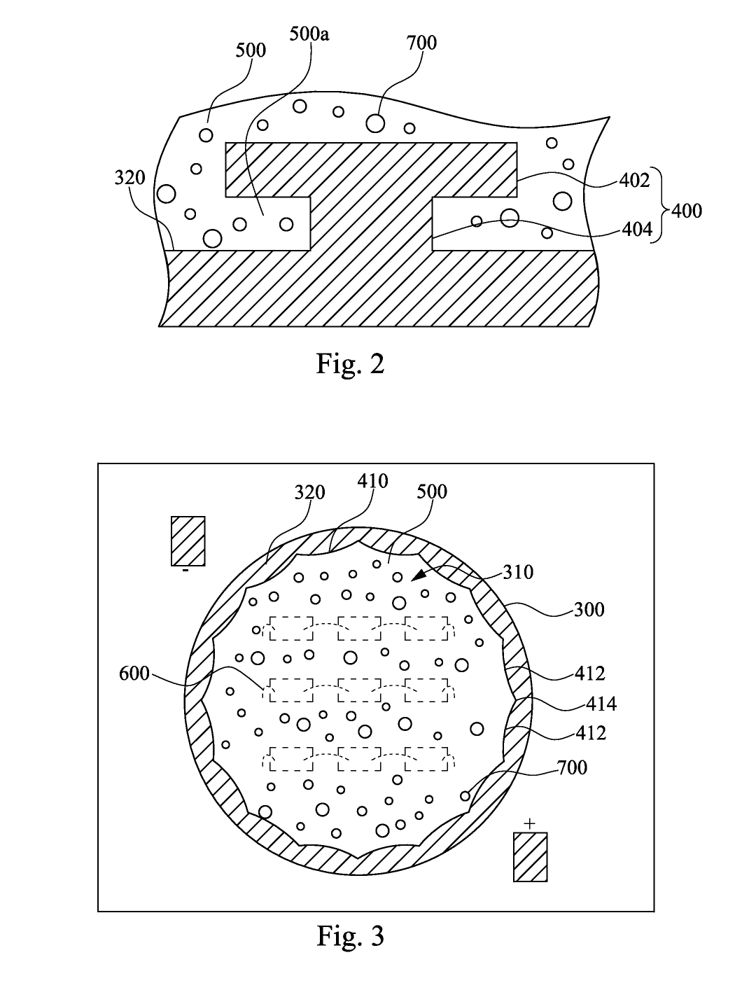

FIG. 2 is a partial top view of the illumination component package in FIG. 1. As shown in FIG. 2, the glue adhering microstructure 400 is a T-shaped member. Specifically, the glue adhering microstructure 400 includes an extrusion member 402 and a connection member 404. One end of the connection member 404 is connected to the inner wall 320 of the dam 300, and another end of the connection member 404 is connected to the extrusion member 402. The cross-sectional area of the extrusion member 402 is greater than the cross-sectional area of the connection area 404. In other words, in top view, the extrusion member 402 is wider than the connection member 404, and therefore, the extrusion member 402 and the connection member 404 cooperate to form the T-shaped member.

Because the T-shaped configuration, the extrusion member 402 and the inner wall 320 can cooperate to hold the encapsulating glue 500, so that the adhering strength between the encapsulating glue 500, the glue adhering microstructures 400 and the inner wall 320 can be improved, thereby preventing the moisture from penetrating therebetween. Further, because part of the encapsulating glue 500a is held between the extrusion member 402 and the inner wall 320, when the encapsulating glue 500a expands or contracts due to the temperature variation, the extrusion member 402 and the inner wall 320 can resist the force from the encapsulating glue 500a, so as to prevent the encapsulating glue 500a peeling from the inner wall 320.

Alternatively, the glue adhering microstructures 400 can be formed by punching on the dam 300. Alternatively, the glue adhering microstructure 400 and the dam 300 can be formed by injection molding. Alternatively, the glue adhering microstructures 400 can be formed by sticking on the inner wall 320 of the dam 300.

In some embodiments, the illumination component 200 is a light emitting diode (LED). Specifically, the illumination component 200 can be an unpackaged LED chip, which is mounted on the substrate 100 by chip-on-board (COB). The LED chip can be, but is not limited to be, a red LED chip, a green LED chip, a blue LED chip or an ultraviolet LED chip.

In some embodiments, the illumination component package includes a wire 600 electrically connected to the illumination component 200. The wire 600 is not only used to electrically connect two adjacent illumination components 200, but also is used to connect the illumination component 200 with the circuit layer (not shown) on the substrate 100, so as to provide electricity to the illumination component 200. In some embodiments, the wire 600 can be, but is not limited to be, a gold line.

In some embodiments, the encapsulating glue 500 includes a wavelength converting material 700. Specifically, the wavelength converting material 700 can be doped in the encapsulating glue 500, and can be stimulated by the light emitted by the illumination component 200, so that the wavelength of the light emitted by the illumination component 200 can be converted after the light stimulates the wavelength converting material 700. In some embodiments, the wavelength converting material 700 can be phosphor, pigment, dye or any combination thereof. For example, the wavelength converting material 700 can be, but is not limited to be, red, green, yellow or blue phosphor.

### Embodiment 2

FIG. 3 is a top view of an illumination component package in accordance with the second embodiment of the present invention. The main difference between this embodiment and the embodiment in FIG. 1 is that: the surfaces 412 of the glue adhering microstructures 410 cooperate to form a wave-shaped ring. Specifically, the surface 412 of each glue adhering microstructure 410 is arc-shaped, and is adjoined with the encapsulating glue 500. The glue adhering microstructures 410 are connected sequentially, and surround the illumination component and the encapsulating glue 500. In other words, the surface 412 of each glue adhering microstructure 410 is connected to the surface 412 of the next glue adhering microstructure 410, thereby forming numerous continuous arc surfaces and forming the wave-shaped ring.

Specifically, the surfaces 412 of two adjacent glue adhering microstructures 410 are connected by an arc turning part 414. In other words, the opposite sides of the arc turning part 414 are connected to arc surfaces 412 with different curvature.

Because the surfaces 412 of the glue adhering microstructures 410 cooperate to form the wave-shaped ring, the contact area between the glue adhering microstructure 410 and the encapsulating glue 500 can be increased, so that the adhering strength between the glue adhering microstructure 410 and the encapsulating glue 500 can be improved, thereby preventing the moisture from penetrating therebetween and preventing the peeling.

In this embodiment, the dam 300 can be a circular ring, and the glue adhering microstructures 410 can be distributed on the inner surface of the dam 300, and thereby form the wave-shaped ring.

Alternatively, the glue adhering microstructures 410 can be formed by punching on the dam 300. Alternatively, the glue adhering microstructure 410 and the dam 300 can be formed by injection molding. Alternatively, the glue adhering microstructures 410 can be formed by sticking on the inner wall 320 of the dam 300.

### Embodiment 3

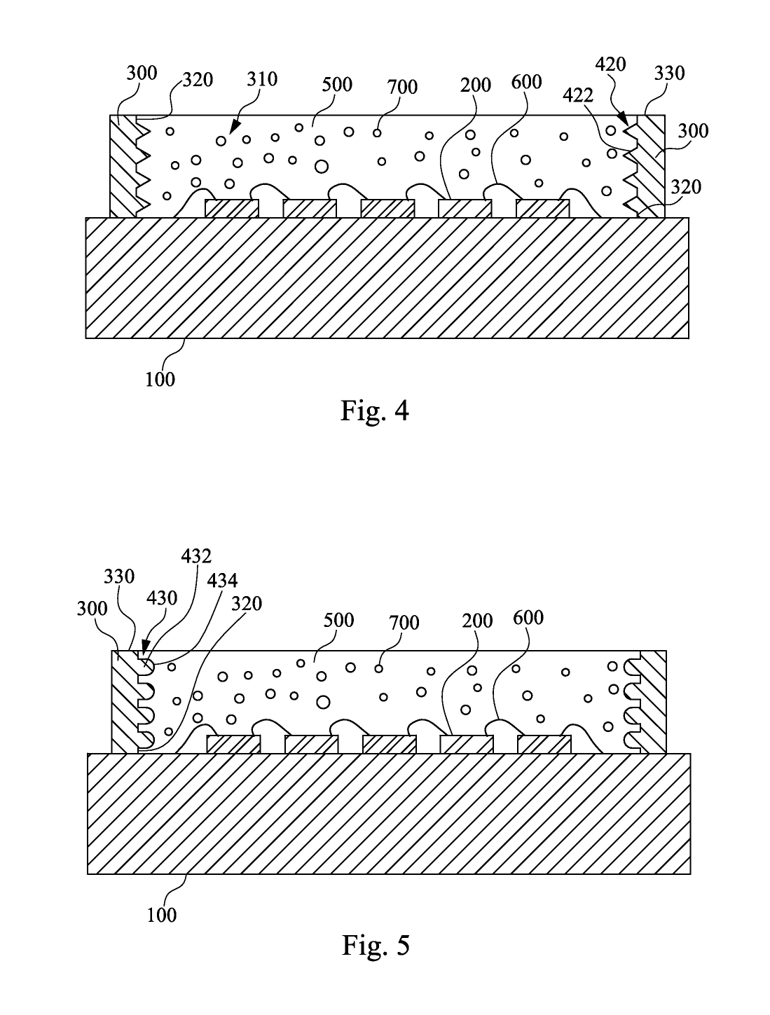

FIG. 4 is a cross-sectional view of an illumination component package in accordance with the third embodiment of the present invention. The main difference between this embodiment and the embodiment in FIG. 3 is that: the glue adhering microstructures 420 are protrusions 422 arranged along the longitudinal cross section of the inner wall 320 of the dam 300. Specifically, the protrusions 422 are protruded on the inner wall 320 of the dam 300, and they are arranged along the direction from the substrate 100 toward the top surface 330 of the dam 300.

Because the protrusions 422 are arranged along the longitudinal cross section of the inner wall 320 of the dam 300, they can prevent the moisture penetrating along the inner wall 320 from the top surface 330 toward the substrate 100, thereby prevent the peeling.

In this embodiment, the protrusions 422 are cone-shaped. Specifically, the protrusions 422 are tapered along the direction from the inner wall 320 of the dam 300 toward the illumination component 200. Further, in this embodiment, the dam 300 is higher than the top surface of the illumination component 200 to prevent the illumination component 200 from exposing in the environment.

The method for manufacturing the cone-shaped protrusions 422 is described as follows. Put a mold with a cone-shaped recess on the substrate 100. Spray or inject the material of the protrusions 422 on the inner wall 320 of the dam 300 before the dam 300 is cured. Heat the material of the protrusions 422 and the dam 300. Remove the mold and leave the dam 300 and the cone-shaped protrusions 422.

Except for the foregoing method, a drill bit with the screw thread thereon can be used to drill into the dam 300, so that protrusions 422 can be formed on the inner wall 320 of the dam 300. The shape of the protrusions 422 matches with the screw thread of the drill bit.

Embodiment 4

FIG. 5 is a cross-sectional view of an illumination component package in accordance with the fourth embodiment of the present invention. The main difference between this embodiment and the embodiment in FIG. 4 is that: the glue adhering microstructures 430 are column-shaped protrusions 432. Specifically, the protrusion 432 is a column, and the end 434 of the protrusion 432 distal to the dam 300 is hemispherical. Because the protrusions 432 are arranged along the longitudinal cross section of the inner wall 320 of the dam 300, they can prevent the moisture penetrating along the inner wall 320 from the top surface 330 toward the substrate 100, thereby prevent the peeling.

The method for manufacturing the column-shaped protrusions 432 is described as follows. Put a mold with a column-shaped recess on the substrate 100. Spray or inject the material of the protrusions 432 on the inner wall 320 of the dam 300 before the dam 300 is cured. Heat the material of the protrusions 432 and the dam 300. Remove the mold and leave the dam 300 and the column-shaped protrusions 432.

### Embodiment 5

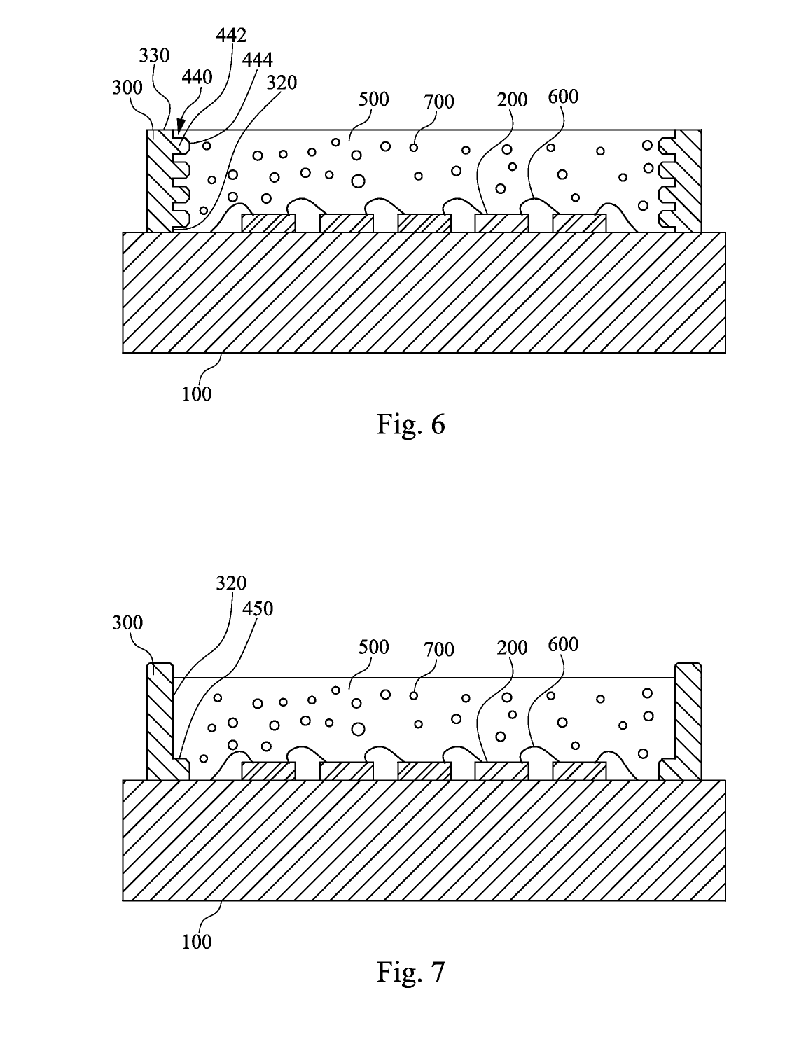

FIG. 6 is a cross-sectional view of an illumination component package in accordance with the fifth embodiment of the present invention. The main difference between this embodiment and the embodiment in FIG. 5 is that: the glue adhering microstructures 440 are prism-shaped protrusions 442. Specifically, the protrusion 442 is a polygonal prism, and the end 444 of the protrusion 442 distal to the dam 300 is trapezoidal. Because the protrusions 442 are arranged along the longitudinal cross section of the inner wall 320 of the dam 300, they can prevent the moisture penetrating along the inner wall 320 from the top surface 330 toward the substrate 100, thereby prevent the peeling.

The method for manufacturing the prism-shaped protrusions 442 is described as follows. Put a mold with a prism-shaped recess on the substrate 100. Spray or inject the material of the protrusions 442 on the inner wall 320 of the dam 300 before the dam 300 is cured. Heat the material of the protrusions 442 and the dam 300. Remove the mold and leave the dam 300 and the prism-shaped protrusions 442.

### Embodiment 6

FIG. 7 is a cross-sectional view of an illumination component package in accordance with the sixth embodiment of the present invention. The main difference between this embodiment and the foregoing embodiments is that: the dam 300 and the glue adhering microstructure 450 form an L-shaped member. Specifically, the glue adhering microstructure 450 is extended from the inner wall 320 of the dam 300 proximal to the substrate 100 toward the illumination component 200, so that the dam 300 and the glue adhering microstructure 450 can form the L-shaped member. In some embodiments, the glue adhering microstructure 450 is disposed on the substrate 100. In other words, the glue adhering microstructure 450 contacts with the substrate 100.

Because the glue adhering microstructure 450 and the dam 300 form the L-shaped member, the contacting area between the encapsulating glue 500 and the glue adhering microstructure 450 and the dam 300 can be increased, so as to prevent the moisture from penetrating therebetween and to prevent the peeling.

In this embodiment, the method to form the glue adhering microstructures 450 on the inner wall 320 of the dam 300 includes, but is not limited to include, spraying and dispensing, punching, molding injection, stacking or screen printing.

### Embodiment 7

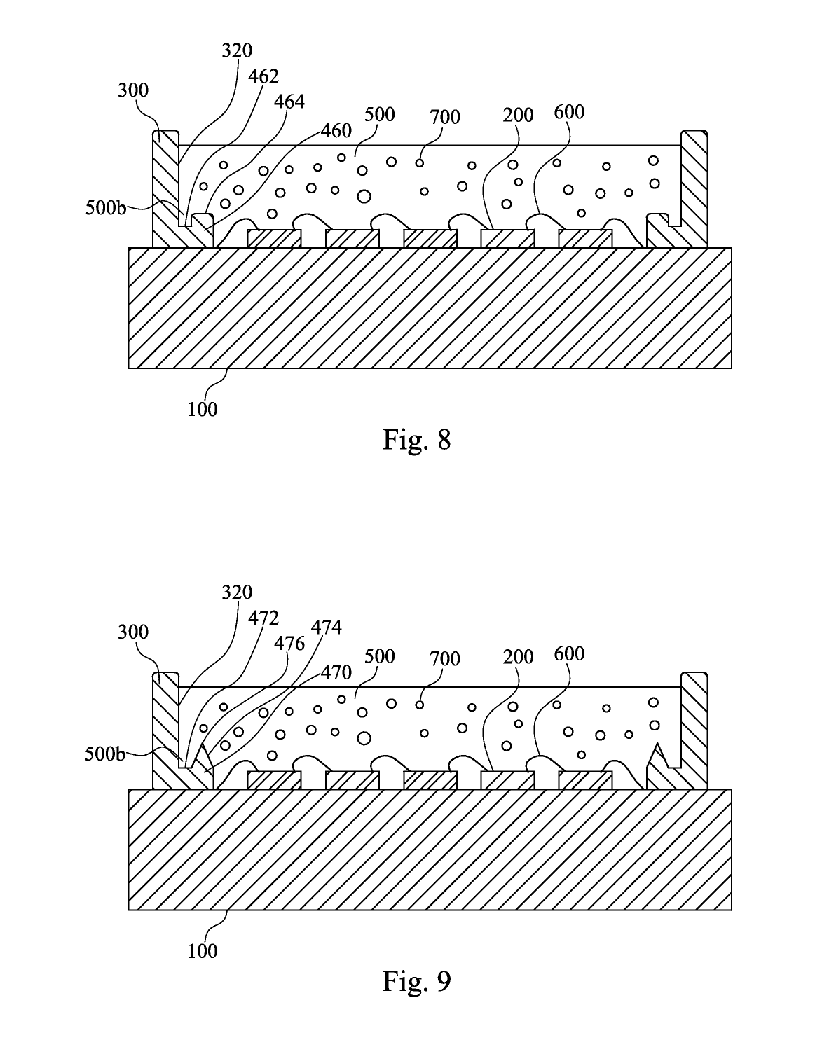

FIG. 8 is a cross-sectional view of an illumination component package in accordance with the seventh embodiment of the present invention. The main difference between this embodiment and the embodiment in FIG. 7 is that: the glue adhering microstructure 460 includes a top surface 462 and at least one elevated structure 464. The top surface 462 is opposite to the substrate 100, and the elevated structure 464 is disposed on the top surface 462 of the glue adhering microstructure 460.

Because a elevated structure 464 is disposed on the top surface 462 of the glue adhering microstructure 460, the contacting area between the encapsulating glue 500 and the glue adhering microstructure 460 and the dam 300 can be increased, so as to prevent the moisture from penetrating therebetween and to prevent the peeling. Further, because part of the encapsulating glue 500b is held between the elevated structure 464 and the inner wall 320, when the encapsulating glue 500b expands or contracts due to the temperature variation, the elevated structure 464 and the inner wall 320 can resist the force from the encapsulating glue 500b, so as to prevent the encapsulating glue 500b peeling from the inner wall 320.

Although only single elevated structure 464 is depicted, in practice, plural elevated structures 464 can be employed, and these elevated structures 464 can be arranged on the top surface 462 of the glue adhering microstructure 460.

In this embodiment, the elevated structure 464 can be parallel to the dam 300. Specifically, the lengthwise direction of the elevated structure 464 is parallel to the inner wall 320 of the dam 300. In this embodiment, the elevated structure 464 is column-shaped.

In this embodiment, the elevated structure 464 and the glue adhering microstructure 460 can be integrally formed, and the forming method includes, but is not limited to include, spraying and dispensing, punching, molding injection, stacking or screen printing.

### Embodiment 8

FIG. 9 is a cross-sectional view of an illumination component package in accordance with the eighth embodiment of the present invention. The main difference between this embodiment and the embodiment in FIG. 8 is that: the elevated structure 474 of the glue adhering microstructure 470 is cone-shaped. Specifically, the elevated structure 474 stands on the top surface 472 of the glue adhering microstructure 470. The elevated structure 474 is tapered along the direction away from the top surface 472 of the glue adhering microstructure 470, and includes a tip 476, so that the elevated structure 474 can be cone-shaped.

Because part of the encapsulating glue 500b is held between the elevated structure 474 and the inner wall 320, when the encapsulating glue 500b expands or contracts due to the temperature variation, the elevated structure 474 and the inner wall 320 can resist the force from the encapsulating glue 500b, so as to prevent the encapsulating glue 500b peeling from the inner wall 320.

In this embodiment, the elevated structure 474 and the glue adhering microstructure 470 can be integrally formed, and the forming method includes, but is not limited to include, spraying and dispensing, punching, molding injection, stacking or screen printing.

### Embodiment 9

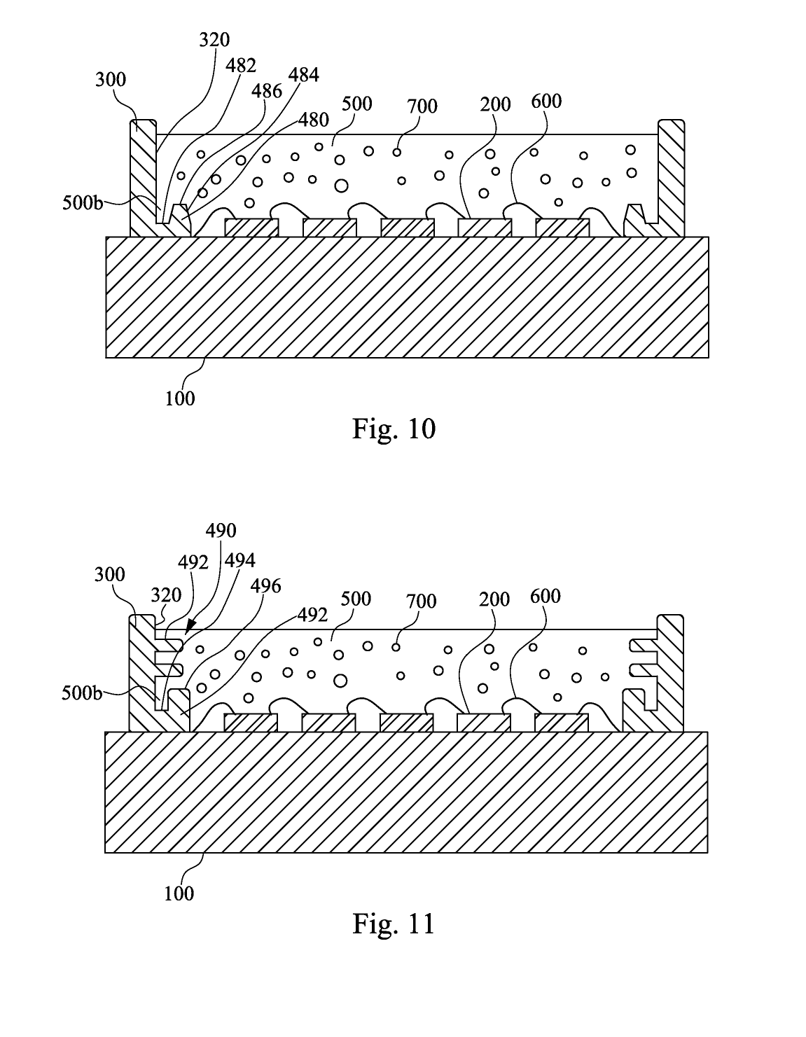

FIG. 10 is a cross-sectional view of an illumination component package in accordance with the ninth embodiment of the present invention. The main difference between this embodiment and the embodiment in FIG. 9 is that: the elevated structure 484 of the glue adhering microstructure 480 is prism-shaped. Specifically, the elevated structure 484 stands on the top surface 482 of the glue adhering microstructure 480. The elevated structure 484 is trapezoidal in the cross-sectional view. Further, because part of the encapsulating glue 500b is held between the elevated structure 484 and the inner wall 320, when the encapsulating glue 500b expands or contracts due to the temperature variation, the elevated structure 484 and the inner wall 320 can resist the force from the encapsulating glue 500b, so as to prevent the encapsulating glue 500b peeling from the inner wall 320.

In this embodiment, the elevated structure 484 and the glue adhering microstructure 480 can be integrally formed, and the forming method includes, but is not limited to include, spraying and dispensing, punching, molding injection, stacking or screen printing.

### Embodiment 10

FIG. 11 is a cross-sectional view of an illumination component package in accordance with the tenth embodiment of the present invention. The main difference between this embodiment and the embodiment in FIG. 10 is that: the glue adhering microstructures 490 are protrusions 492, and these protrusions 492 are arranged along the longitudinal cross section of the inner wall 320 of the dam 300. One of the protrusions 492 includes a top surface 494 and at least one elevated structure 496. The top surface 494 is opposite to the substrate 100. The elevated structure 496 is disposed on the top surface 494 of the glue adhering microstructure 490 (namely, the protrusion 492).

In this embodiment, the protrusion 492 with the elevated structure 496 is disposed on the substrate 100. In other words, the protrusion 492 with the elevated structure 496 contacts with the substrate 100.

The inner wall 320 not only includes numerous protrusions 492, one of the protrusion 492 but also includes the elevated structure 496, and therefore, the contacting area between the dam 300 and the encapsulating glue 500 can be significantly increased, thereby improving the adhering strength between the dam 300 and the encapsulating glue 500, thereby preventing the moisture from penetrating therebetween and preventing the peeling issue. Further, because part of the encapsulating glue 500b is held between the elevated structure 496 and the inner wall 320, when the encapsulating glue 500b expands or contracts due to the temperature variation, the elevated structure 496 and the inner wall 320 can resist the force from the encapsulating glue 500b, so as to prevent the encapsulating glue 500b peeling from the inner wall 320.

In this embodiment, the lengthwise direction of the protrusion 492 is parallel to the substrate 100, and the lengthwise direction of the elevated structure 496 is parallel to the inner wall 320 of the dam 300. In this embodiment, the lengthwise direction of the protrusion 492 and the lengthwise direction of the elevated structure 496 are substantially perpendicular to each other.

In this embodiment, the protrusion 492 is column-shaped, but in other embodiments, the protrusion 492 can also be cone-shaped or prism-shaped. In this embodiment, the elevated structure 496 is column-shaped, but in other embodiments, the elevated structure 496 can also be cone-shaped or prism-shaped.

It is noted that the description “the feature A is disposed on the feature B” in this specification not only refers to the embodiment that the feature A directly contacts with the feature B, but also refers to the embodiment that an additional feature C is intervened between the feature A and the feature B. For example, “the illumination component 200 is disposed on the substrate 100” not only includes the embodiment that the illumination component 200 directly contacts with the substrate 100, but also includes the embodiment that an additional material, such as heat dissipation glue or heat dissipation layer, is intervened between the illumination component and the substrate 100.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An illumination component package, comprising:
a substrate;
at least one illumination component mounted on the substrate;
a dam surrounding the illumination component to form a accommodating space, wherein an inner wall of the dam comprises a plurality of glue adhering microstructures; and
an encapsulating glue filled in the accommodating space.

2. The illumination component package of claim 1, wherein the glue adhering microstructures are arranged along the direction of the dam surrounding the illumination component.

3. The illumination component package of claim 2, wherein each of the glue adhering microstructures is a T-shaped member.

4. The illumination component package of claim 2, wherein the surfaces of the glue adhering microstructures cooperate to form a wave-shaped ring.

5. The illumination component package of claim 1, wherein the glue adhering microstructures are protrusions arranged along the longitudinal cross section of the inner wall of the dam.

6. The illumination component package of 5, wherein each of the protrusions is cone-shaped, column-shaped, or prism-shaped.

7. The illumination component package of claim 1, wherein the dam and the glue adhering microstructure form an L-shaped member.

8. The illumination component package of claim 7, wherein the glue adhering microstructure is disposed on the substrate.

9. The illumination component package of claim 7, wherein the glue adhering microstructure comprises at least one elevated structure disposed on the top surface of the glue adhering microstructure opposite to the substrate.

10. The illumination component package of claim 9, wherein the elevated structure is parallel to the dam.

11. The illumination component package of claim 9, wherein the elevated structure is cone-shaped, column-shaped, or prism-shaped.

12. The illumination component package of claim 1, wherein the glue adhering microstructures are protrusions arranged along the longitudinal cross section of the inner wall of the dam, wherein one of the protrusions comprises at least one elevated structure disposed on the top surface of the glue adhering microstructures opposite to the substrate.

13. The illumination component package of claim 1, further comprising a wire electrically connected to the illumination component.

14. The illumination component package of claim 1, wherein the illumination component is a light emitting diode (LED).

15. The illumination component package of claim 1, wherein the dam is higher than the top surface of the illumination component.

16. The illumination component package of claim 1, wherein the encapsulating glue comprises wavelength converting material.

17. The illumination component package of claim 16, wherein the wavelength converting material comprises phosphor, pigment, dye or any combination thereof.
